(19) United States
(12) Patent Application Publication
(10) Pub. No.: US 2023/0386828 A1
(43) Pub. Date: Nov. 30, 2023

(54) PRE-TREATMENT APPARATUS

(71) Applicant: Taiwan Semiconductor Manufacturing Co., Ltd., Hsinchu (TW)

(72) Inventors: Chun-Hsiang WANG, Tainan City (TW); Kai Yuan CHAN, Tainan City (TW); Po-Chung CHENG, Chiayi County (TW); Chien Chou KO, Tainan County (TW)

(73) Assignee: Taiwan Semiconductor Manufacturing Co., Ltd., Hsinchu (TW)

(21) Appl. No.: 18/188,929

(22) Filed: Mar. 23, 2023

Related U.S. Application Data
(60) Provisional application No. 63/385,732, filed on Dec. 1, 2022.
(60) Provisional application No. 63/346,644, filed on May 27, 2022.

(51) Int. Cl. H01L 21/02; C23C 16/455; C23C 16/458; C23C 16/46

(52) U.S. Cl. CPC H01L 21/02222; C23C 16/45519; C23C 16/4583; C23C 16/46

(57) ABSTRACT

A pre-treatment apparatus can be added as a module of a wafer track system, where the pre-treatment is designed to reduce friction at the edges of a substrate. Reducing edge friction can help prevent back side edge particles during attachment to a vacuum chuck in a subsequent processing operation that can occur, for example, in an exposure device. The pre-treatment apparatus can be configured to deliver one or more gases to treat top and/or bottom surfaces of a substrate. The pre-treatment apparatus can treat back side edges of a substrate to reduce edge friction of the substrate and to prevent overlay defects.

### CROSS-REFERENCE TO RELATED APPLICATION

This patent application claims benefit of U.S. Provisional Patent Application No. 63/385,732, filed on Dec. 1, 2022 and titled “Pre-Treatment Apparatus,” and U.S. Provisional Patent Application No. 63/346,644, filed on May 27, 2022 and titled “HMDS Hybrid Coating Plate,” which are incorporated by reference herein in their entireties.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs). Such scaling down has increased the complexity of semiconductor manufacturing processes and their vulnerability to both particle defects and alignment-related defects.

### BRIEF DESCRIPTION OF THE DRAWINGS

Aspects of the present disclosure are best understood from the following detailed description when read with the accompanying figures. It is noted that, in accordance with common practice in the industry, various features are not drawn to scale. In fact, the dimensions of the various features may be arbitrarily increased or reduced for clarity of discussion.

FIG. 1 is a block diagram of a wafer track system that includes a pre-treatment apparatus for reducing registration edge defects, in accordance with some embodiments of the present disclosure.

FIG. 2 is a flow diagram of a method for reducing registration edge defects, in accordance with some embodiments of the present disclosure.

FIG. 3 is a cross-sectional view showing details of the pre-treatment apparatus shown in FIG. 1, in accordance with some embodiments of the present disclosure.

FIGS. 4A-4C illustrate a result of incorporating pre-treatment apparatus into the wafer track system shown in FIG. 1, in accordance with some embodiments of the present disclosure.

FIGS. 5A and 5B are semiconductor wafer maps showing cumulative defects from various stages of a semiconductor wafer fabrication process, in accordance with some embodiments of the present disclosure.

### DETAILED DESCRIPTION

The following disclosure provides different embodiments, or examples, for implementing different features of the provided subject matter. Specific examples of components and arrangements are described below to simplify the present disclosure. These are, of course, merely examples and are not intended to be limiting. For example, the formation of a first feature on a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “nominal” as used herein refers to a desired, or target, value of a characteristic or parameter for a component or a process operation, set during the design phase of a product or a process, together with a range of values above and/or below the desired value. The range of values can be due to slight variations in manufacturing processes or tolerances.

The terms “wafer,” “semiconductor wafer,” and “substrate” as referred to herein are used interchangeably and are meant to encompass any type of semiconductor wafer, whether it is a bare semiconductor wafer or a partially processed semiconductor wafer onto which one or more materials or film stacks has been deposited and/or patterned.

In some embodiments of the present disclosure, the terms “about” and “substantially” can indicate a value of a given quantity that varies within 20% of the value (for example, ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

The term “vertical,” as used herein, means perpendicular to the surface of a substrate.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

In a semiconductor manufacturing process for integrated circuits, semiconductor wafers are subjected to a series of mask patterning operations for patterning various layers of material deposited onto the semiconductor wafers. At each successive layer, the corresponding mask patterning operation can occur in a multi-operation spin-expose-develop sequence. In the spin operation, a photoresist mask is applied to the semiconductor wafer as a viscous liquid polymer that can be dispensed at the semiconductor wafer center and spun to distribute the photoresist evenly over the semiconductor wafer surface. In the expose operation, the photoresist is exposed to an energy source in an exposure device, under vacuum, that chemically modifies selected regions of the photoresist according to a mask pattern. In the develop operation, the treated photoresist processed using a chemical developer to selectively remove either the exposed portions or the unexposed portions of the photoresist. Equipment used to perform the spin-expose-develop sequence can be arranged on a wafer track system as a spin processing module, an expose processing module, and a develop processing module. In addition to the spin, expose, and develop modules, the wafer track system can include one or more heating modules and one or more cooling modules that prepare the semiconductor wafers for the spin, expose, and develop operations.

Prior to the expose operation, the semiconductor wafer can be aligned so that it can be positioned in substantially the same orientation for every mask patterning operation. This ensures that patterns formed on the semiconductor wafer at different layers will overlay one another to achieve a prescribed electronic circuit design. The relative positioning of subsequent mask patterns can be referred to herein as “registration.” If the alignment is not accurate, registration errors can distort the mask pattern. Such distortions in the mask pattern can be detectable at an in-line metrology operation as an overlay shift defect, where the pattern is shifted relative to corresponding patterns on lower mask layers. Distorted mask patterns can be more problematic than particulate type defects that can be removed by cleaning because mask pattern distortions or errors are permanently transferred to the underlying layer by subsequent etching processes.

In addition to registration errors, if particles accumulate under the semiconductor wafer, the pattern can be interrupted or deformed, which can also appear as an in-line defect. Further, if the semiconductor wafer can be bowed such that it does not lie substantially flat during the expose operation, registration defects can result. To prevent such defects, the semiconductor wafer can be positioned on a vacuum chuck to ensure the semiconductor wafer remains substantially flat during the expose operation. However, as a bowed semiconductor wafer flattens while the center is pulled toward the chuck by the vacuum, the perimeter of the semiconductor wafer can scrape against the chuck causing particles to accumulate at the back side edges. These edge particles can further degrade the registration.

Embodiments of the present disclosure describe a method and apparatus for reducing friction at the wafer edge to prevent particle generation occurring from motion during the vacuum chucking procedure. When friction is reduced, fewer particles are generated that can result in mask pattern defects at the edge of the semiconductor wafer. Additional advantages/benefits of the present disclosure include, among other things, re-use of an existing process chemical and modification of existing equipment used for other purposes within the mask patterning process. Whenever materials and equipment can be re-purposed in this way, there is an opportunity for manufacturing cost savings. For example, when a new use is found for a chemical that is already used for semiconductor processing, the proper safety protocols are already in place, as well as the logistics system for supplying the chemical and the delivery system for feeding it to the processing equipment. Likewise, the processing equipment has already been qualified to dispense that chemical, the delivery lines are already plumbed to the equipment, the support infrastructure for the equipment is already in place, and the equipment will not require additional floor space in the fabrication facility.

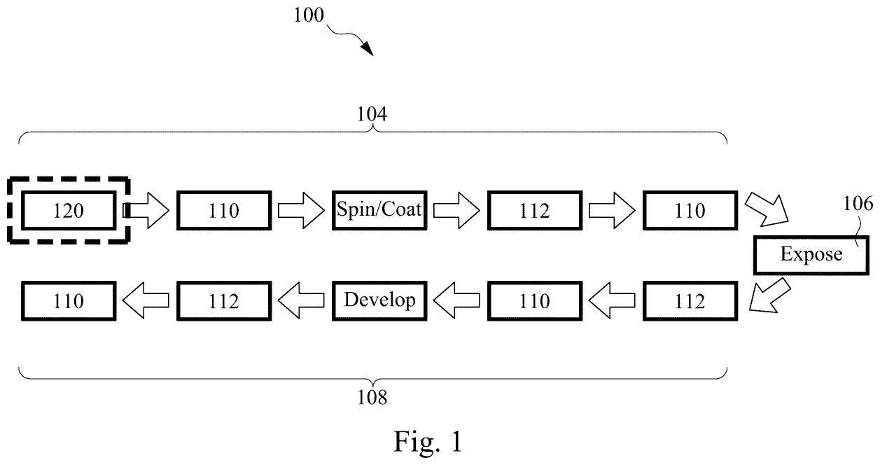

FIG. 1 illustrates a wafer track system 100 supporting a spin-expose-develop processing sequence for mask patterning of a substrate 102, according to some embodiments of the present disclosure. Wafer track system 100 includes one or more pre-processing (spin/coat) modules 104, an exposure device 106, and one or more post-processing (develop) modules 108. Pre-processing modules 104 and post-processing modules 108 can further include one or more cooling plate modules 110 and one or more hot plate modules 112.

Semiconductor wafers move through wafer track system 100 in the direction shown by the arrows in FIG. 1 to prepare for exposure device 106 and to recover from exposure device 106, according to some embodiments of the present disclosure. In some embodiments of the present disclosure, exposure device 106 can be, for example, a stepper or a scanner that exposes photoresist on a top surface of substrate 102 to an energy source. Exposure device 106 can use light in the visible, ultra violet, deep ultra violet, or other suitable spectrum wavelengths to expose the photoresist. Or, exposure device 106 can use an electron beam, or any other suitable techniques, to execute the expose operation to create a photoresist mask pattern on substrate 102.

In some embodiments of the present disclosure, a pre-treatment apparatus 120 can be added to wafer track system 100, as one of pre-processing modules 104. In some embodiments of the present disclosure, pre-treatment apparatus 120 can be a module (for example, the first module) of wafer track system 100. Pre-treatment apparatus 120, shown in a dashed line box in FIG. 1, can be designed to reduce friction at the edges of substrate 102. Reducing edge friction can help prevent generating back side edge particles when attaching substrate 102 to a vacuum chuck in a subsequent processing operation that can occur, for example, in exposure device 106. In some embodiments of the present disclosure, pre-treatment apparatus 120 can be configured to deliver one or more gases to treat top or bottom surfaces of substrate 102. In some embodiments of the present disclosure, pre-treatment apparatus 120 can apply an adhesion promoter to a top surface of substrate 102. In some embodiments of the present disclosure, pre-treatment apparatus 120 can treat a top edge and/or a bottom edge of substrate 102 to reduce edge friction of substrate 102. In some embodiments of the present disclosure, pre-treatment apparatus 120 can serve multiple functions, for example, pre-treatment apparatus 120 can be used to apply an adhesion promoter to a top surface of substrate 102 while also treating back side edges of substrate 102.

Cooling plate modules 110 and hot plate modules 112 serve to prepare the semiconductor wafers for processing in the various track modules. Because photoresist is a viscous liquid polymer, its properties can change with temperature. Therefore, characteristics of the photoresist can be optimized prior to, or after, processing at the spin/coat, expose, and develop modules. For example, cooling plate modules 110 can cool down the semiconductor wafers after exposure to an energy source. Likewise, hot plate modules 112 can alter or maintain the viscosity of the photoresist prior to exposure. Pre-treatment apparatus 120 is engaged prior to processing with either cooling plate modules 110 or hot plate modules 112 and can therefore be independent of the alterations that temperature variation can impose on the photoresist. Further, treatments made to semiconductor wafers by pre-treatment apparatus 120 can be coordinated with the use of cooling plate modules 110 and hot plate modules 112 to provide the most advantageous sequence through wafer track system 100.

In some embodiments of the present disclosure, substrate 102 can be a semiconductor wafer at any stage of the semiconductor manufacturing process, including any number of pre-formed layers. Materials added to substrate 102 may be patterned or may remain unpatterned. Furthermore, substrate 102 can include one or more of a wide array of semiconductor materials, such as (i) an elementary semiconductor, such as germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Alternatively, substrate 102 can be made from an electrically non-conductive material, such as a glass wafer, a sapphire wafer, or a plastic substrate. In some embodiments of the present disclosure, substrate 102 can be a bulk semiconductor wafer or the top semiconductor layer of a semiconductor-on-insulator (SOI) wafer (not shown). In some embodiments of the present disclosure, substrate 102 can include a crystalline semiconductor layer with its top surface 102, parallel to a (100), (110), (111), or c-(0001) crystal plane. Substrate 102 can be made of a semiconductor material such as, but is not limited to, silicon (Si). Further, substrate 102 can be doped with p-type dopants (for example, boron (B), indium (In), aluminum (Al), or gallium (Ga)) or n-type dopants (for example, phosphorus (P) or arsenic (As)). In some embodiments of the present disclosure, different portions of substrate 102 can have opposite type dopants.

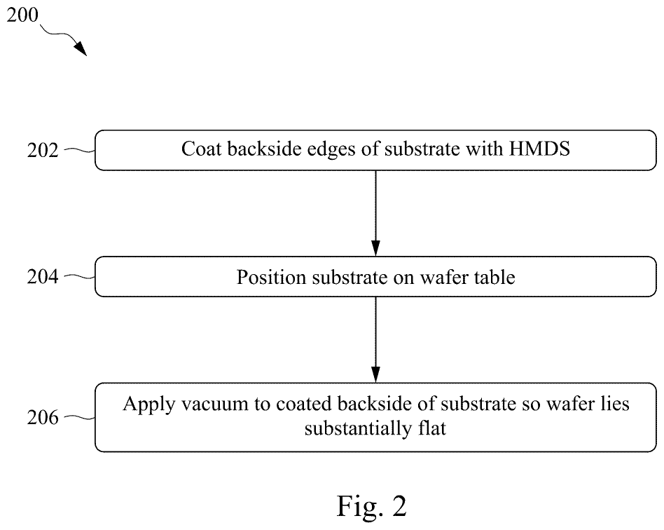

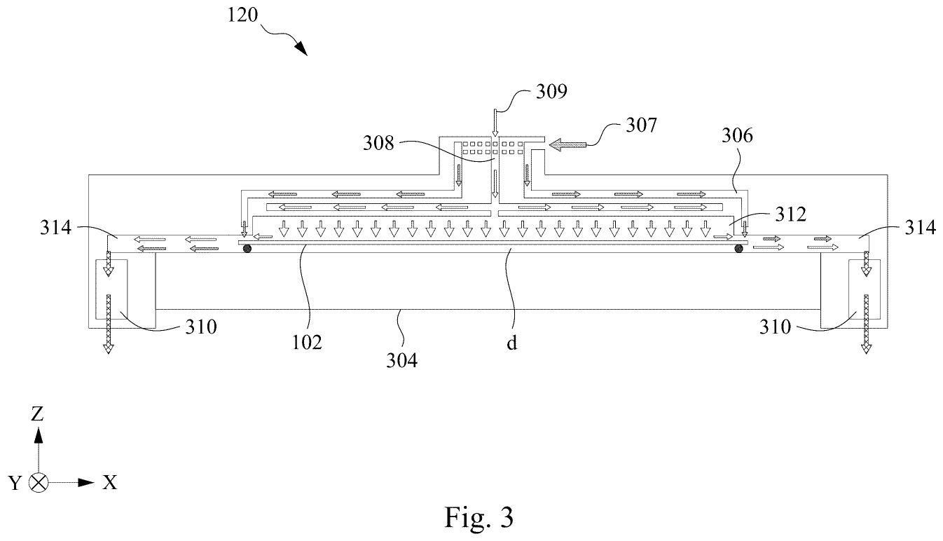

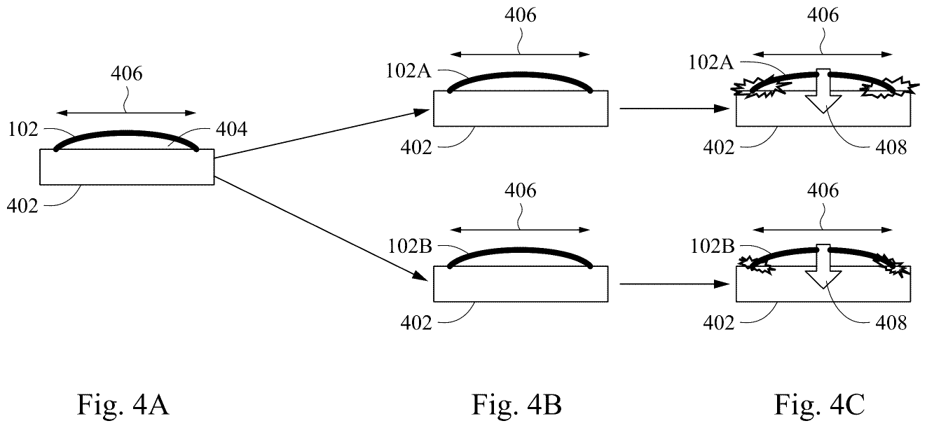

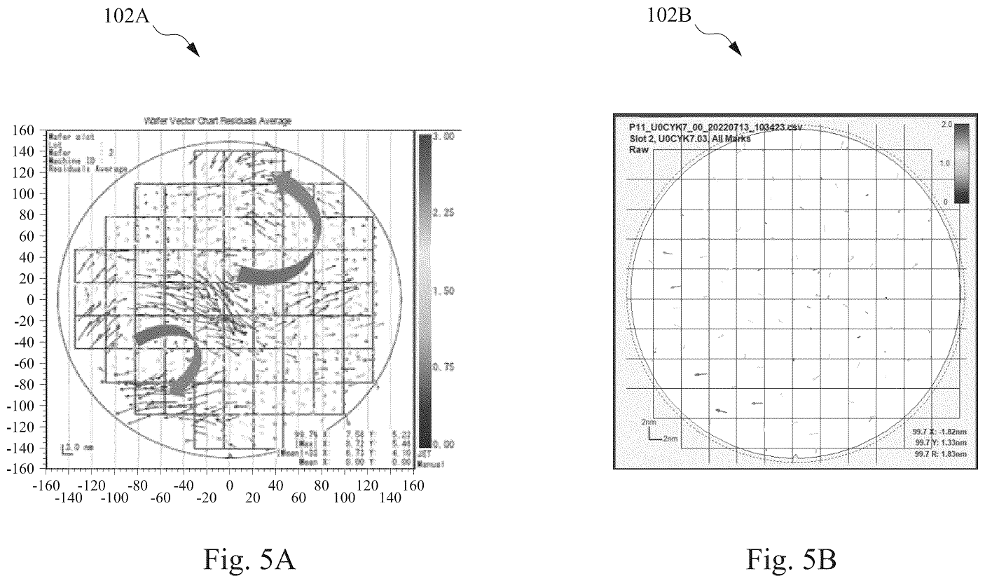

FIG. 2 illustrates a method 200 for processing substrate 102 using pre-treatment apparatus 120 on wafer track system 100, according to some embodiments of the present disclosure. For illustrative purposes, operations illustrated in FIG. 2 will be described with reference to processes for coating substrate 102 as illustrated in FIG. 3, FIG. 4, FIG. 5A, and FIG. 5B, according to some embodiments of the present disclosure. Operations of method 200 can be performed in a different order, or not performed, depending on specific applications. It is noted that method 200 may not prevent all registration defects at the edge of substrate 102. Accordingly, it is understood that additional processes can be provided before, during, or after method 200, and that some of these additional processes may be briefly described herein.

Referring to FIG. 2, at operation 202, back side edges of substrate 102 can be coated with a friction reducing material, as shown in FIG. 3, according to some embodiments of the present disclosure. FIG. 3 illustrates pre-treatment apparatus 120, according to some embodiments of the present disclosure. In some embodiments of the present disclosure, components of pre-treatment apparatus 120 can include a semiconductor wafer table 304, or plate, a first gas inlet channel 306, a second gas inlet channel 308, and one or more gas exhaust ports 310. In some embodiments of the present disclosure, substrate 102 rests on (for example, directly on) semiconductor wafer table 304 while being processed in pre-treatment apparatus 120. In some embodiments of the present disclosure, substrate 102 can be spaced apart from semiconductor wafer table 304 by a distance d of between about 0.9 mm and about 1.1 mm. When substrate 102 is spaced apart from semiconductor wafer table 304, the spacing can contribute to pattern distortion and registration defects. In some embodiments of the present disclosure, semiconductor wafer table 304 can be configured as a hot plate to heat and maintain substrate 102 at a temperature between about 108° C. and about 132° C.

In some embodiments of the present disclosure, first and second gas inlet channels 306 and 308 can be pressurized to direct gas flow in a prescribed flow pattern, for example, upward, downward, or sideways, relative to substrate 102. In some embodiments of the present disclosure, first gas inlet channel 306 can contain a coating gas 307 such as, for example, hexamethlydisilazane or hexamethlydisilazide (HMDS) in vapor form. HMDS is an organosilicon compound that can be used as a molecular precursor in chemical vapor deposition (CVD) processes. For example, HMDS can be used to deposit silicon carbide nitride (SiCN) thin film coatings onto glass, thereby causing the glass to become hydrophobic. HMDS can also be used as an adhesion promoter to improve the adhesion of photoresist to various materials deposited onto semiconductor wafers. When used as an adhesion promoter, HMDS is used to treat the top surface of substrate 102 before applying photoresist to ensure the photoresist adheres to the substrate 102.

In some embodiments of the present disclosure, HMDS vapor can be re-purposed as a coating gas 307 to coat back side edges of substrate 102 prior to further processing in the spin/expose/develop modules along wafer track system 100. In some embodiments of the present disclosure, first gas inlet channel 306 can be configured to direct a flow of coating gas 307 downward and towards the center of substrate 102, towards the surface of substrate 102, radially outward along a top surface of substrate 102, at a height substantially above the surface of substrate 102, and around the edges of substrate 102. For example, coating gas 307 can be maintained a few mm above the surface of substrate 102. In some embodiments of the present disclosure, a coating flow rate of coating gas 307 can be in a range of about 2.25 liters/minute to about 2.75 liters/minute. In some embodiments of the present disclosure, a coating pressure of coating gas 307 can be in the range of about 1.4 kPa to about 1.8 kPa. In some embodiments of the present disclosure, coating gas 307 can be directed away from substrate 102 everywhere except at the back side edges of substrate 102. In some embodiments of the present disclosure, coating gas 307 can be permitted to accumulate at the back side edges of substrate 102, before being directed into exhaust port(s) 310 for disposal.

In some embodiments of the present disclosure, second gas inlet channel 308 can contain an inert purge gas 309, such as a nitrogen gas (N₂). In some embodiments of the present disclosure, a purge pressure of inert purge gas 309 can be in the range of about 1.4 kPa to about 1.8 kPa. In some embodiments of the present disclosure, a purge flow rate of inert purge gas 309 can be in the range of about 4.5 liters/minute to about 5.5 liters/minute.

Second gas inlet channel 308 can be configured to direct inert purge gas 309 simultaneously along two different paths—downward and towards the center of substrate 102, as well as radially outward along a top surface of substrate 102, according to some embodiments of the present disclosure. A downward flow of inert purge gas 309 can be directed towards an enclosure 312 that provides access to the top surface of substrate 102. Inert purge gas 309 can then spread out within enclosure 312, along the entire surface area of substrate 102 to fill enclosure 312 and to continue flowing around the edges of substrate 102 towards exhaust port 310. The downward flow path of inert purge gas 309 thus serves to flush the top surface of substrate 102 to dilute any HMDS that may backflow into enclosure 312, according to some embodiments of the present disclosure. Meanwhile, the radial flow path of inert purge gas 309 serves to maintain a positive outward pressure gradient, directed away from substrate 102, to prevent HMDS from back flowing and coating the top surface of substrate 102. Thus, in some embodiments of the present disclosure, the portion of substrate 102 in contact with HMDS is the back side edge of substrate 102.

In some embodiments of the present disclosure, first gas inlet channel 306 and second gas inlet channel 308 can merge at the edge of substrate 102 into a single channel 314 near exhaust port(s) 310. Within single channel 314, the respective gases flowing in first gas inlet channel 306 and second gas inlet channel 308 can mix prior to being pushed out from pre-treatment apparatus 120 through exhaust ports 310. In single channel 314, inert purge gas 309 can therefore serve to dilute coating gas 307 prior to disposal. In some embodiments of the present disclosure, channel 314 can include multiple channel portions to dilute coating gas 307 prior to disposal.

Advantages/benefits of the channel design shown in FIG. 3 are evident when comparing the design to other designs for applying adhesion promoters prior to the spin/coat module. By re-routing gas lines and exhaust lines, and thus making minimal modifications to an assembly that already uses HDMS for improved adhesion, a new purpose is pursued that implements existing materials and equipment, and thus provides a new defect reduction capability at a lower cost.

Referring to FIG. 2, at operations 204 and 206, substrate 102 can be processed in exposure device 106, according to some embodiments of the present disclosure. While being processed in exposure device 106, substrate 102 can be positioned on a semiconductor wafer table 402 as shown in FIG. 4A, FIG. 4B, and FIG. 4C. In some embodiments of the present disclosure, semiconductor wafer table 402 can be a stage internal to a processing chamber (for example, a vacuum chamber) of exposure device 106. In some embodiments of the present disclosure, a substrate 102 can be held above a top surface of semiconductor wafer table 402 such that portions of substrate 102, for example, a central region of substrate 102 is initially spaced apart from semiconductor wafer table 402 by an air gap 404. In some embodiments of the present disclosure, air gap 404 can be between about 0.9 mm to about 1.1 mm.

In some embodiments of the present disclosure, semiconductor wafer table 402 can be equipped with a vacuum chuck, electrostatic chuck, or any other suitable mechanism configured to reduce air gap 404 so as to cause substrate 102 to lie substantially flat on semiconductor wafer table 402 during processing in exposure device 106. Such mechanisms associated with semiconductor wafer table 402 can subject substrate 102 to one or more forces, such as a radial force 406 arising from an application of a downward pressure 408. In some embodiments of the present disclosure, semiconductor wafer table 402 can be configured to create an external force that exerts downward pressure 408 to hold substrate 102 substantially flat so that the back side of substrate 102 is substantially in contact with semiconductor wafer table 402.

Referring to FIG. 2, at operation 204, substrate 102 can be processed in exposure device 106 at an initial time, according to some embodiments of the present disclosure. Initially, when substrate 102 is positioned on semiconductor wafer table 402 as shown in FIG. 4A, downward pressure 408 is not yet being applied, and substrate 102 may not lie substantially flat on semiconductor wafer table 402. Depending on various conditions and factors that can exert internal forces on substrate 102, the semiconductor wafer may be bowed, thus forming a gap 404 between substrate 102 and semiconductor wafer table 402. In some embodiments of the present disclosure, gap 404 can have a radial variation. Such conditions and factors can include, for example, how many layers of material are on substrate 102, which types of materials are present on substrate 102, which materials are adjacent to one another either vertically or horizontally, the temperature of substrate 102, the thermal mass of substrate 102 including its various layers, and so on. Each of these variables can influence the size of gap 404 and therefore how much contact semiconductor wafer 102 has with semiconductor wafer table 402. For example, each layer of material that is present on substrate 102 will expand and contract in response to temperature changes during further processing, thus giving rise to differential lateral and vertical forces. A net vertical force can result in the wafer bowing in the center. In FIG. 4A, because the vacuum is off, both the downward pressure 408 and an associated radial force 406 on the bowed semiconductor wafer are substantially zero so that substrate 102 remains stationary.

Referring to FIG. 2, at operation 206, substrate 102 can be placed in contact with semiconductor wafer table 402, as shown in FIG. 4B and FIG. 4C, according to some embodiments of the present disclosure. The top views shown in FIG. 4B and FIG. 4C illustrate what happens to a substrate 102A that was not treated with HMDS when placed on semiconductor wafer table 402; the bottom views shown in FIG. 4B and FIG. 4C illustrate what happens to a substrate 102B that was pre-treated with HMDS in pre-treatment module 120, as described above, when placed on semiconductor wafer table 402.

In some embodiments of the present disclosure, semiconductor wafer tables 402 are activated to apply downward pressure 408 to the back sides of substrates 102A and 102B, thus causing gap 404 to close. As gap 404 closes and substrates 102A and 102B straighten and flatten out against respective semiconductor wafer tables 402, the perimeters of substrates 102A and 102B experience radial friction forces 406 that can cause edges of substrates 102A and 102B to slide on semiconductor wafer tables 402. Due to the pre-treatment with HMDS described above, radial friction force 406 on substrate 102B in the lower view of FIG. 4B can be reduced so that substrate 102B slides easier against semiconductor wafer table 402 as compared to substrate 102A against semiconductor wafer table 402.

Put differently, untreated substrate 102A shown in the top views experiences a large radial friction force 406 that can cause the wafer to shed particles from its back side edge. As particles accumulate on the back side of untreated substrate 102A, the back side particles can cause the top surface of the semiconductor wafer to be tilted at an angle. When the tilted semiconductor wafer is later transferred to exposure device 106 for exposing the photoresist, the tilt can cause optical reflections that can corrupt the pattern in a localized area of the top surface at the edge, corresponding to the particles located on the opposite back surface at the edge.

FIGS. 5A and 5B are cumulative semiconductor wafer maps corresponding to untreated substrate 102A (FIG. 5A) and pre-treated substrate 102B with HMDS (FIG. 5B), respectively, according to some embodiments of the present disclosure. The cumulative semiconductor wafer maps overlay particle data from multiple operations in the semiconductor manufacturing process, as opposed to single semiconductor wafer maps that would show a snapshot in time of the present particle signature. The cumulative semiconductor wafer maps shown in FIGS. 5A and 5B can be obtained from in-line metrology operations, such as optical semiconductor wafer surface scanners. In each cumulative semiconductor wafer map, the circle represents the perimeter of the semiconductor wafer, and the inscribed squares represent chips, or dies, that will be cut from the semiconductor wafer. Dies showing a large defect density are generally not viable. However, if the defects are particle defects, such dies can potentially be salvaged using semiconductor wafer cleaning techniques. On the other hand, if the defects are pattern defects, such as mis-alignment and pattern blur that result from poor registration, such defects cannot be corrected once the pattern is physically transferred to the underlying material layer by etching. Defects that are only detectable on a cumulative semiconductor wafer map are therefore particularly problematic because, by the time they are detected, it may be too late to correct them.

Untreated substrate 102A shown in FIG. 5A indicates traces of registration defects originating at the edge of substrate 102A, attributable to successive exposure operations while processing through wafer track system 100 at various layers in the semiconductor manufacturing process. In some embodiments of the present disclosure, the registration defects may represent particles due to radial friction force 406. In some embodiments of the present disclosure, the registration defects may represent poor alignment due to semiconductor wafer bowing. In some embodiments of the present disclosure, the large defect density shown in FIG. 5A can be associated with a significant decrease in chip yield. In contrast, treated substrate 102B shown in FIG. 5B indicates an improvement in cumulative defects at wafer track system 100 operations, which could correspond to a significant yield improvement.

Embodiments of the present disclosure describe a pre-treatment apparatus that can be added as a module of a wafer track system, where the pre-treatment apparatus is designed to reduce friction at the edges of a substrate to reduce the likelihood of generating associated mask pattern defects at the edges of the substrate. Reducing edge friction can help prevent back side edge particles during attachment to a vacuum chuck in a subsequent processing operation that can occur, for example, in an exposure device downstream of the pre-treatment apparatus within the wafer track system. The pre-treatment apparatus can be configured to deliver one or more gases to treat top and/or bottom surfaces of a substrate and to coat back side edges of the substrate. In particular, the pre-treatment apparatus can treat back side edges of a substrate to reduce edge friction of the substrate and to prevent overlay defects. For example, a coating gas can be directed to flow around the semiconductor substrate while an inert purge gas can be directed to flush the top surface of the semiconductor substrate to prevent backflow of the coating gas. Additional advantages/benefits of the present disclosure include, among other things, re-purposing of an existing process chemical, and re-use of existing pre-installed equipment that is presently used for other purposes within the mask patterning process.

In some embodiments of the present disclosure, a method includes: applying a coating to back side edges of a substrate; positioning the substrate on a wafer table in an exposure device; and applying a vacuum to the coated back side of the substrate to cause the substrate to lie substantially flat on the wafer table.

In some embodiments of the present disclosure, an apparatus includes: a plate configured to hold a substrate above a top surface of the plate; a first gas inlet channel configured to direct a coating gas to edges of the substrate so the coating gas will accumulate between the substrate and the top surface of the plate; a second gas inlet channel configured to direct a purge gas to a top surface of the substrate; and an exhaust port configured to direct the purge gas and the coating gas away from the substrate.

In some embodiments of the present disclosure, a method includes: positioning a substrate on a plate; directing a coating gas through a first gas inlet channel to coat back side edges of the substrate; directing an inert purge gas through a second gas inlet channel to a top surface of the substrate; and directing the inert purge gas and the coating gas away from the substrate to an exhaust port.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
applying a coating to back side edges of a substrate;
positioning the substrate on a wafer table in an exposure device; and
applying a vacuum to the coated back side of the substrate to cause the substrate to lie substantially flat on the wafer table.

2. The method of claim 1, wherein coating the back side edges of the substrate comprises directing hexamethlydisilazane (HMDS) vapor to the substrate.

3. The method of claim 2, further comprising flowing a purge gas onto a top surface of the substrate to prevent the HMDS vapor from coating the top surface of the substrate.

4. The method of claim 1 wherein applying the coating to the back side edges of the substrate comprises spacing the substrate away from a hot plate by a distance of about 1 mm.

5. An apparatus, comprising:
a plate configured to hold a substrate above a top surface of the plate;
a first gas inlet channel configured to direct a coating gas to edges of the substrate so the coating gas will accumulate between the substrate and the top surface of the plate;
a second gas inlet channel configured to direct an inert purge gas to a top surface of the substrate; and
an exhaust port configured to direct the inert purge gas and the coating gas away from the substrate.

6. The apparatus of claim 5, wherein the inert purge gas comprises nitrogen gas (N₂).

7. The apparatus of claim 5, wherein the coating gas comprises hexamethlydisilazane (HMDS).

8. The apparatus of claim 5, wherein the plate is configured to be set at a temperature between about 108° C. and about 132° C. when the coating gas and purge gas are directed to the substrate.

9. The apparatus of claim 5, wherein the second gas inlet channel is configured to direct the purge gas at a purge flow rate of about 5 liters/minute.

10. The apparatus of claim 5, wherein the second gas inlet channel is configured to direct the purge gas at a purge pressure of about 1.6 kPa.

11. The apparatus of claim 5, wherein the second gas inlet channel is configured to direct the coating gas at a coating flow rate of about 2.5 liters/minute.

12. The apparatus of claim 5, wherein the first gas inlet channel is configured to direct the coating gas at a coating pressure of about 1.6 kPa.

13. A method, comprising:
positioning a substrate on a plate;
directing a coating gas through a first gas inlet channel to coat back side edges of the substrate;
directing an inert purge gas through a second gas inlet channel to a top surface of the substrate; and
directing the inert purge gas and the coating gas away from the substrate to an exhaust port.

14. The method of claim 13, wherein directing the coating gas through the first gas inlet channel comprises flowing an organosilicon gas to coat the back side edges of the substrate.

15. The method of claim 14, wherein directing the coating gas through the first gas inlet channel comprises flowing the coating gas away from the substrate so that the coating gas contacts the substrate solely at the back side edges of the substrate.

16. The method of claim 13, wherein directing the inert purge gas through the second gas inlet channel comprises flowing nitrogen gas (Na) downward across the top surface of the substrate to prevent the coating gas from contacting the top surface of the substrate.

17. The method of claim 13, wherein directing the inert purge gas through the second gas inlet channel comprises flowing N₂ to fill an enclosure above the top surface of the substrate.

18. The method of claim 13, wherein directing the purge gas through the second gas inlet channel comprises flowing N₂ between the first gas channel and the top surface of the substrate.

19. The method of claim 13, wherein directing the inert purge gas comprises flowing N₂ at a flow rate about two times greater than a flow rate of the coating gas.

20. The method of claim 13, wherein directing the inert purge gas through the second gas inlet channel comprises flowing N₂ laterally and vertically above the top surface of the substrate.
